(19) United States
(12) Patent Application Publication
(10) Pub. No.: US 2026/0130212 A1
(43) Pub. Date: May 7, 2026

(54) ELECTRONIC DEVICE

(71) Applicant: DENSO CORPORATION, Kariya-city (JP)

(72) Inventor: Kazuya HIRASAWA, Kariya-city (JP)

(21) Appl. No.: 19/374,660

(22) Filed: Oct. 30, 2025

(30) Foreign Application Priority Data
Nov. 1, 2024 (JP) 2024-192989

(51) Int. Cl. H01L 23/367; H01L 23/40

(52) U.S. Cl. CPC H10W 40/22; H10W 40/625

(57) ABSTRACT

An electronic device includes a housing, a substrate disposed in the housing, a package component, a heat sink, and load-bearing components. The package component includes a chip and is mounted on the substrate. The heat sink is disposed between the housing and the chip, and joined to the chip. The load-bearing components are disposed on an extended region of the heat sink where the heat sink extends outward of the package component when viewed in a thickness direction of the substrate. The load-bearing components press the heat sink in a direction from the substrate toward the heat sink.

### CROSS REFERENCE TO RELATED APPLICATION

This application is based on and incorporates herein by reference Japanese Patent Application No. 2024-192989 filed on Nov. 1, 2024.

### TECHNICAL FIELD

The present disclosure relates to an electronic device including, for example, a chip.

### BACKGROUND

Conventionally, a technique is known in which a heat-generating component such as a semiconductor chip is mounted on a substrate via solder.

### SUMMARY

According to at least one embodiment of the present disclosure, an electronic device includes a housing, a substrate disposed in the housing, a package component, a heat sink, and load-bearing components. The package component includes a chip and is mounted on the substrate. The heat sink is disposed between the housing and the chip, and joined to the chip. The load-bearing components may be disposed on an extended region of the heat sink where the heat sink extends outward of the package component when viewed in a thickness direction of the substrate. The load-bearing components press the heat sink in a direction from the substrate toward the heat sink.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a cross-sectional view showing a schematic structure of an electronic device according to a first embodiment.

FIG. 2 is a cross-sectional view showing an enlarged view of a package component of the electronic device and its periphery.

FIG. 3 is a bottom view showing a box body of a housing viewed from an opening of the box body.

FIG. 4 is a planar view of the electronic device viewed in a thickness direction (i.e., up down direction) showing an arrangement of a lid, a heat sink, and the package component.

FIG. 5 is a planar view showing the package component viewed from above.

FIG. 6 is a cross-sectional view of an electronic device in the thickness direction, showing a schematic structure of the electronic device according to a second embodiment.

FIG. 7 is a cross-sectional view of an electronic device in the thickness direction, showing a schematic structure of the electronic device according to a third embodiment.

FIG. 8 is a perspective view showing a heat sink according to the third embodiment viewed from a frame body.

FIG. 9 is a planar view showing a substrate including a notch through which a load-bearing component passes.

### DETAILED DESCRIPTION

According to a comparative example, a heat-generating component such as a semiconductor chip is mounted on a substrate via ball-shaped solder (i.e., BGA solder). In this technique, a heat-dissipating member is brought into contact with a surface of the heat-generating component (i.e., a surface facing away the substrate), and the substrate and the heat-dissipating member are integrated with a screw.

As a result of the detailed exploration of the inventor, it has been founded that when the substrate and the heat-dissipating member are integrated with the screw, the heat-generating component and the solder arranged between the substrate and the heat-dissipating member are subjected to a load caused by the fastened screw. Therefore, if an excessive load (i.e., stress) is applied to the solder, the solder may deform, potentially causing a short circuit.

In contrast to the comparative example, according to the present disclosure, an excessive load can be prevented from being applied to a solder.

An electronic device according to one embodiment of the present disclosure includes a housing, a substrate disposed in the housing, a package component including a chip and mounted on the substrate via solder, and a heat sink disposed between the housing and the chip and joined to the chip.

Multiple load-bearing components are disposed on an extended region of the heat sink where the heat sink extends outward of the package component when viewed in a thickness direction of the substrate. The multiple load-bearing components press the heat sink in a direction from the substrate toward the heat sink.

In the present disclosure, such a configuration can reduce an excessive load applied to the solder. In other words, in the present disclosure, the multiple load-bearing components are disposed on the extended region of the heat sink where the heat sink extends outward of the package component. As a result, even when the load-bearing components press the heat sink in the direction from the substrate toward the heat sink, the load is not applied to the solder. Therefore, since the load applied to the solder can be reduced, the solder is less likely to deform, and an occurrence of short circuits due to deformation of the solder can be prevented.

Hereinafter, exemplary embodiments of the present disclosure will be described with reference to the drawings. In the following embodiments, portions that are the same as or equivalent to those described in a preceding embodiment are denoted by the same reference numerals, and a description of the same or equivalent portions may be omitted. When only some of the configuration elements are described in the embodiment, the remaining configuration elements can be referred from those described in the preceding embodiment. The following embodiments may be partially combined with each other even if such a combination is not explicitly described as long as there is no disadvantage with respect to such a combination.

### First Embodiment

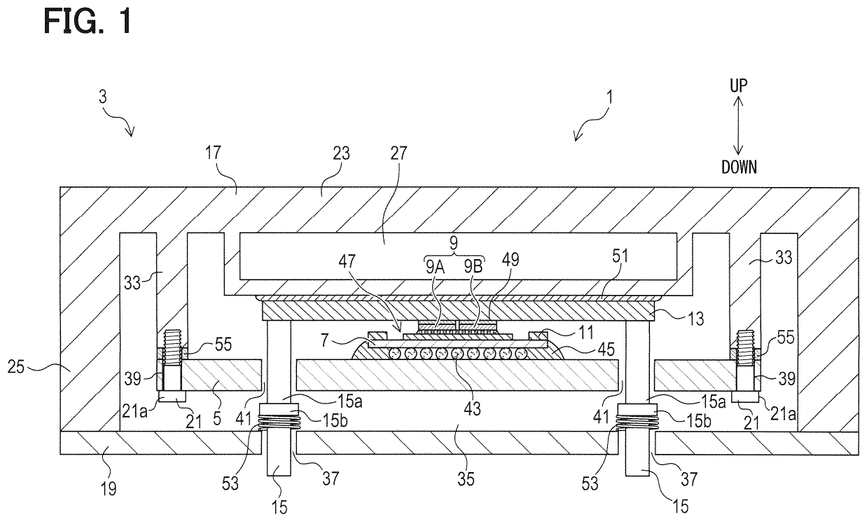

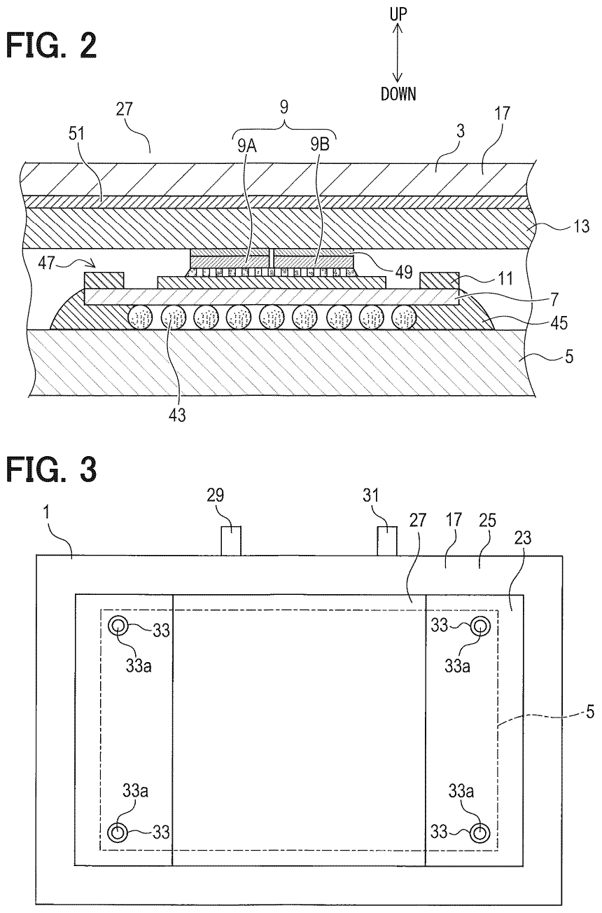

As shown in FIGS. 1 and 2, an electronic device (e.g., electronic control unit) 1 includes a housing 3, a substrate 5, an interposer 7, multiple chips 9 (e.g., chips 9A and 9B), a stiffener 11, a heat sink 13, and multiple load-bearing components 15.

The housing 3 has a rectangular parallelepiped shape and includes a box body 17 and a lid 19 (i.e., cover). The substrate 5 is secured in the housing 3 by multiple (e.g., four) fasteners (e.g., screws) 21. The interposer 7 is mounted on the substrate 5. The multiple chips 9 are mounted on the interposer 7. The chips 9 are, for example, semiconductor chips as heat-generating components. The heat sink 13 is joined to the chips 9 and is pressed by the load-bearing components 15.

Hereinafter, as shown in FIG. 1, in a thickness direction of the substrate 5 (i.e., up down direction in FIG. 1), one side of the substrate 5 facing the heat sink 13 is referred to as an “upper” side, the other side of the substrate 5 facing the lid 19 is referred to as a “lower” side. Additionally, the view in the thickness direction is referred to as an “A view.”

Hereinafter, each configuration will be described in detail. As shown in FIG. 1, the box body 17 of the housing 3 has an opening on the lower side, and includes a rectangular plate-shaped portion 23 and a side portion 25. In the A view, the side portion surrounds the plate-shaped portion 23. The box body 17 is, for example, a die-casting product made of an aluminum alloy.

A cooling section 27 is provided on the lower side of a central portion of the plate-shaped portion 23 of the box body 17. The cooling section 27 has a rectangular parallelepiped shape, protrudes from the lower side of the plate-shaped portion 23 so as to face the heat sink 13, and is integrated with the box body 17. The cooling section 27 is, for example, a cooler having a water-cooling structure. Specifically, a portion protrudes downward from the lower side of the central portion of the box body 17, and this protruding portion serves as the cooling section 27. A cavity is formed inside the cooling section 27, and cooling water, which serves as a coolant, is allowed to flow into the interior of the cooling section 27. As shown in FIG. 3, an inlet 29 and an outlet 31 for the cooling water are provided on the side portion 25 of the box body 17.

Furthermore, as shown in FIG. 1, four columns 33 (refer to FIG. 3), to which four fasteners 21 are respectively attached, extend downward from a lower face of the plate-shaped portion 23 of the box body 17. As shown in FIG. 3, the columns 33 are arranged at four corners of the plate-shaped portion 23 (i.e., at positions corresponding to four vertices of the rectangular shape), in the A view from below. A screw hole 33a, into which a tip end of a fastener 21 is screwed, is provided at an end of each of the columns 33.

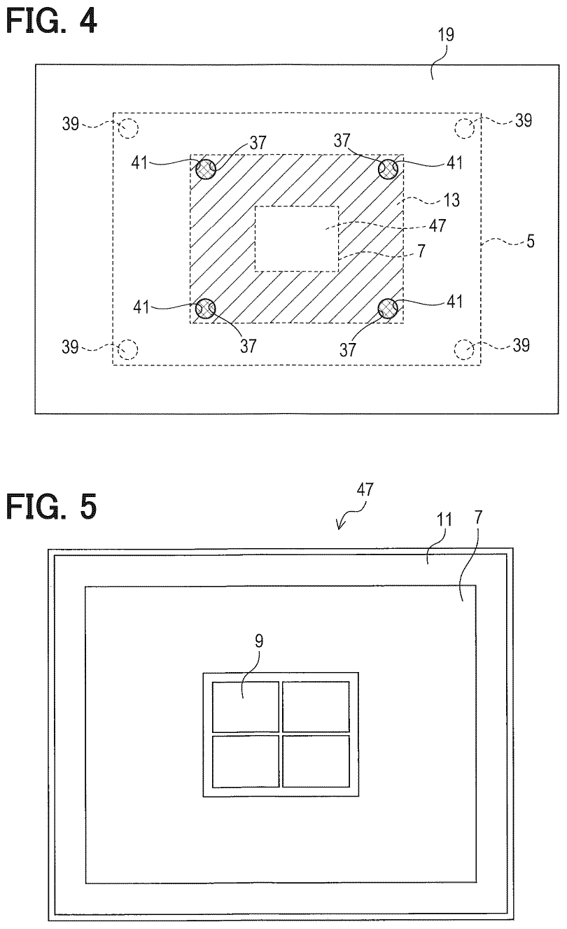

As shown in FIG. 4, the lid 19 of the housing 3 is a plate member which has a rectangular shape in the A view and covers an opening 35 of the box body 17. The lid 19 may be made of a material such as an aluminum alloy or iron. The lid 19 includes four lower-end through-holes 37. A lower end of each of the load-bearing components 15 extends through a lower-end through-hole 37. The lower-end through-holes 37 are arranged at positions of the vertices of the rectangular shape, corresponding to the positions of the four load-bearing components 15.

As shown in FIG. 1, since the lid 19, the substrate 5, the interposer 7, and the heat sink 13 are arranged in this order from the lower side, FIG. 4 illustrates a state in which the lid 19, the substrate 5, the interposer 7, and the heat sink 13 are stacked and viewed from the lower side.

The substrate 5 is a known printed circuit board (i.e., PCB) and has a rectangular shape in the A view. The substrate 5 includes fastening through-holes 39, through which the fasteners 21 are inserted, at four corners of the substrate 5. Additionally, the substrate 5 includes load-bearing through-holes 41, through which the load-bearing components 15 extend, at four corners of an area inward of positions where the fastening through-holes 39 are arranged. The lower-end through-holes 37 and the load-bearing through-holes 41 coincide in position with each other in the A view.

As shown in FIG. 2, the interposer 7 includes a wiring electrically connecting between the multiple chips 9, and a wiring electrically connecting the multiple chips 9 and the substrate 5. The interposer 7 and the substrate 5 are electrically connected via solder balls 43 (i.e., BGA solder) arranged in a grid pattern. BGA is an abbreviation of Ball Grid Array. Additionally, a side fill 45 is deposited between the interposer 7 and the substrate 5, and on a periphery of the interposer 7. The side fill 45 reinforces a bonding strength between the interposer 7 and the substrate 5.

The stiffener 11 is mounted on an upper surface of the interposer 7. The stiffener 11 is made of a material such as copper, and serves as a reinforcing member to increase a rigidity of the interposer 7. The stiffener 11 and the interposer 7 are overlapped with each other in the A view from above. In other words, the stiffener 11 has a rectangular-framed shape.

Specifically, a shape and dimension of the stiffener 11 are set such that the entire of an outer periphery of the stiffener 11 is positioned inward of the outer periphery of the interposer 7. In other words, the stiffener 11 is slightly smaller in size than the interposer 7. The multiple chips 9 are arranged at positions surrounded by the frame-shaped stiffener 11. Here, this structure, in which the interposer 7, the stiffener 11, and the chips 9 are integrated, is referred to as a package component (e.g., semiconductor package) 47.

As shown in FIGS. 1 and 2, the heat sink 13, having a rectangular shape in the A view, is joined to upper surfaces of the multiple chips 9 with a joint member 49 (i.e., a solid first heat dissipating member) having heat dissipating performance. The first heat dissipating member 49 may be made of, for example, solder or a thermosetting adhesive.

The heat sink 13 is made of, for example, copper and is deposited so as to cover an upper side of the package component 47. As shown in FIG. 4, the heat sink 13 is larger in size than the package component 47 in the A view, and extends outward of the package component 47 so as to surround its periphery (i.e., its outer circumference) in the A view.

As shown in FIGS. 1 and 2, for example, a highly flexible and gel-like heat dissipating member (i.e., a second heat dissipating member) 51 is provided between the heat sink 13 and the cooling section 27 (specifically, a plate-shaped lower portion 27a that forms a lower side of the cooling section 27). The second heat dissipating member 51 may be made of, for example, a silicone resin, an epoxy resin, or an acrylic resin. These resins may contain fillers having a high thermal conductivity, such as alumina particles.

Next, a structure in which a load is applied to the heat sink 13 will be described. As shown in FIG. 1, the load-bearing components 15, which are members applying the load to the heat sink 13, include cylindrical shaft portions 15a and annular holding portions 15b provided along outer peripheries of the shaft portions 15a.

FIG. 4 is a view showing positions where the shaft portions 15a press the heat sink 13 (i.e., cross-hatched circular portions). The load-bearing components 15 are disposed at these circular positions (i.e., at positions corresponding to the four corners of the heat sink 13) in the A view. In other words, the load-bearing components 15 are arranged at the four positions corresponding to the four corners of the heat sink 13. The four positions are located in an area of the heat sink 13 where the heat sink 13 extends outward of the package component 47 in the A view (i.e., quadrilateral-framed area with diagonal hatching in FIG. 4). The load-bearing components 15 are arranged at the four positions so as to be positioned at the vertices of the rectangular shape of the heat sink 13.

As shown in FIG. 1, upper parts of the shaft portions 15a of the load-bearing components 15 (i.e., portion above the holding portion 15b) extend through the load-bearing through-holes 41 of the substrate 5, and lower parts of the shaft portions 15 a (i.e., portion below the holding portion 15b) extend through the lower-end through-holes 37 of the lid 19. The holding portions 15 b are disposed between the substrate 5 and the lid 19, and springs 53 are disposed between the holding portions 15b and the lid 19.

Since the springs 53 push the holding portions 15b upward, the whole of the load-bearing components 15 are pushed upward accordingly. As a result, the tip ends of the shaft portions 15a press the heat sink 13 upward.

Next, a structure pressing the substrate 5 will be described. As described below, the substrate 5 is pressed upward by the fasteners 21. Additionally, the substrate 5 is placed at a position pressing the package component 47 toward the heat sink 13 in the thickness direction of the substrate 5 (i.e., up-down direction).

As shown in FIG. 1, the substrate 5 is secured by the four fasteners 21 to the four columns 33, which are erected on the plate-shaped portion 23 of the box body 17, via washers 55. The washers 55 are annular members having elasticity (e.g., spring washer or elastic resin). The fasteners 21 are arranged at positions of the fastening through-holes 39 located at four corners of the substrate 5 (refer to FIG. 4). In other words, the fasteners 21 are arranged at positions corresponding to vertices of a rectangular shape in the A view.

Each of the fasteners 21 is a screw having a head 21a. The fasteners 21 secure the substrate 5 to the box body 17 by tips of the fasteners 21 extending through the fastening through-holes 39 of the substrate 5 and being screwed into screw holes 33a of the columns 33 via the washers 55.

Since the washers 55 are compressed by the fasteners 21 being screwed, the substrate 5 can be slightly moved upward. As a result, the package component 47 and the heat sink 13 arranged on an upper surface of the substrate 5 can be pressed upward.

Even when the heat sink 13 is pressed upward by the load-bearing components 15, the substrate 5 (additionally, the package component 47) is pressed by the fasteners 21 being screwed in a direction where the chips 9 and the heat sink 13 become in close contact with each other (i.e., upward).

Next, a method for manufacturing the electronic device 1 will be described. The method described below is one example, various manufacturing methods that can manufacture the electronic device 1 described above are adoptable.

First, the heat sink 13 is joined to the chips 9 of the package component 47 using, for example, solder. In this state, the package component 47 is disposed on the surface of the substrate 5, and the package component 47 is soldered to the substrate 5 by reflow-soldering as well-known. Specifically, the solder balls 43 are heated and melt to join a wiring of the package component 47 and a wiring of the substrate 5 to be electrically conductive therebetween.

Next, the box body 17 is placed such that the opening 35 faces upward. The substrate 5, to which the heat sink 13 and the package component 47 are joined, is placed in the box body 17 with the heat sink 13 facing downward via the second heat dissipating member 51. Specifically, the gel-like second heat-dissipating member 51 is applied to a surface of the cooling section 27, and the substrate 5 is placed on the second heat dissipating member 51 in the box body 17 with the heat sink 13 facing downward.

Next, the four corners of the substrate 5 are secured with the fasteners 21 being screwed. Next, tip ends of the shaft portions 15a of the load-bearing components 15 are inserted into the four load-bearing through-holes 41 of the substrate, respectively. Next, the springs 53 are disposed at rear ends of the shaft portions 15a such that the holding portions 15b are located between the tip ends and the springs 53. Next, the lid 19 is disposed so as to close the opening 35 of the box body 17, and the lid 19 is secured to the box body 17 with screws or other members that are not shown. At this time, the rear ends of the shaft portions 15a of the load-bearing components 15 are inserted through the four lower-end through-holes 37 of the lid 19, respectively.

In addition to the method described above, for example, the heat sink 13 may be joined to upper surfaces of the chips 9 after the package component 47 is reflow-soldered to the substrate 5. For example, the joining may be carried out by locally heating and melting solder or the like.

Next, effects of the first embodiment will be described. The electronic device 1 according to the first embodiment includes the housing 3 (i.e., box body 17), the substrate 5 disposed in the housing 3, the package component 47 (i.e., package component including the chips 9) mounted on the substrate 5 via the solder balls 43 (i.e., BGA solder), and the heat sink 13, which is disposed between the box body 17 and the chips 9 and is joined to the chips 9.

Furthermore, the heat sink 13 extends outward of the package component 47 in the A view, which is viewed in the thickness direction (i.e., up-down direction) of the substrate 5. The four load-bearing components 15 are provided on a surface of the heat sink 13 facing the substrate 5 and arranged in the area where the heat sink 13 extends outward of the package component 47. The load-bearing components 15 press the heat sink 13 upward with the springs 53.

With this configuration, the solder balls 43 can be prevented from receiving an excessive load. In other words, the heat sink 13 extends outward of the package component 47 in the A view, and in the extended region of the heat sink 13, the multiple load-bearing components 15 are arranged on the surface of the heat sink 13 which faces the substrate 5. Therefore, even when the load-bearing components 15 press the heat sink 13 upward in a direction from the substrate 5 to the heat sink 13, the solder balls 43 are prevented from receiving the load. Therefore, since the solder balls 43 can be prevented from receiving the load, the solder balls 43 are less likely to deform, and an occurrence of shorts due to deformation of the solder balls 43 can be prevented.

In the electronic device 1 according to the first embodiment, since the substrate 5 includes the load-bearing through-holes 41, the load-bearing components 15 can be disposed so as to extend through the load-bearing through-holes 41. Therefore, the load-bearing components 15 can press the heat sink 13 via the load-bearing through-holes 41.

In the electronic device 1 according to the first embodiment, the load-bearing components 15 include the holding portions 15b, and the springs 53 are disposed between the lid 19 and the holding portions 15b. Therefore, an elastic force of the springs 53 can press the load-bearing components 15 against the heat sink 13.

In the electronic device 1 according to the first embodiment, when the substrate 5 is secured with the fasteners 21, the substrate 5 press the package component 47 and the heat sink 13 upward. Therefore, even when the load-bearing components 15 press the heat sink 13, the heat sink 13 is less likely to be detached from the chips 9.

In the electronic device 1 according to the first embodiment, the heat sink 13 may have a rectangular shape in the A view. Thus, the load-bearing components 15 may be arranged at positions corresponding to the four corners of the heat sink 13 in the A view. Therefore, the load-bearing components 15 can press the four corners of the heat sink 13.

In the electronic device 1 according to the first embodiment, the chips 9 and the heat sink 13 can joined together with the solid first heat dissipating member 49. As a result, heat dissipating performance is improved.

In the electronic device 1 according to the first embodiment, the second heat dissipating member 51 can be disposed between the heat sink 13 and the cooling section 27 so as to be in contact with both the heat sink 13 and the cooling section 27. As a result, heat dissipation performance is improved.

In the electronic device 1 according to the first embodiment, the housing 3 includes the cooling section 27 at a position facing the heat sink 13 through the second heat dissipating member 51 such that a heat can be released from the heat sink 13 to the cooling section 27 via the second heat dissipating member 51. As a result, heat dissipation performance is improved.

Next, a correspondence between the present disclosure and the present first embodiment will be described. An electronic device corresponds to the electronic device 1, a housing corresponds to the housing 3, a substrate corresponds to the substrate 5, a chip corresponds to the chips 9, 9A, 9B, a heat sink corresponds to the heat sink 13, a load-bearing component corresponds to the load-bearing components 15, a holding portion corresponds to the holding portions 15b, a cooling section corresponds to the cooling section 27, through-holes correspond to the load-bearing through-holes 41, a package component corresponds to the package component 47, a first heat dissipating member corresponds to the first heat dissipating member 49, a second heat dissipating member corresponds to the second heat dissipating member 51, and a spring corresponds to the springs 53.

### Second Embodiment

A basic configuration of a second embodiment is similar to that of the first embodiment, and hence differences from the first embodiment will be mainly described below. The members with the same names as those in the first embodiment have the same functions. The same reference numerals as those in the first embodiment indicate the same configuration, and reference is made to the preceding description.

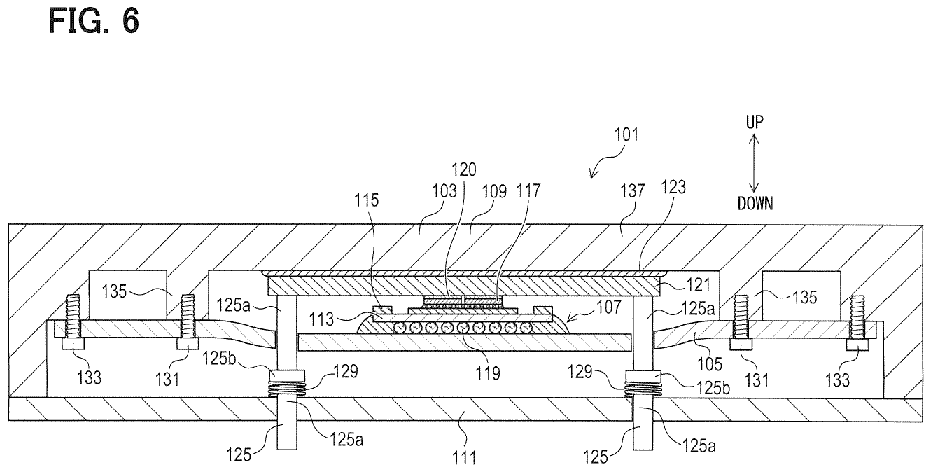

As shown in FIG. 6, an electronic device 101 according to the present second embodiment includes, for example, a housing 103, a substrate 105, and a package component 107. The housing 103 includes a box body 109 and a lid 111. The package component 107 includes. for example, an interposer 113, a stiffener 115, chips 117, and is mounted on the substrate 105 by solder balls 119. The chips 117 are joined to a heat sink 121 via a solid first heat dissipating member 120. A gel-like second heat dissipating member 123 is disposed between the heat sink 121 and a plate-shaped portion 137 of the box body 109.

The present second embodiment, similarly to the first embodiment, includes four load-bearing components 125 that have column shapes. The load-bearing components 125 are pressed upward by springs 129 disposed between the lid 111 and holding portions 125b of the load-bearing components 125. Similarly to the first embodiment, the load-bearing components 125 press the heat sink 121 upward at positions located outward of the package component 107 in the A view. Similarly to the first embodiment, shaft portions 125a of the load-bearing components 125 are disposed so as to penetrate both the substrate 105 and the lid 111.

In this second embodiment, the substrate 105 has a rectangular shape and is disposed so as to cover substantially an entire interior of the box body 109. Similarly to the first embodiment, the substrate 105 is secured with four inner fasteners (i.e., screws) 131, which are disposed at vertices of a rectangular shape, so as to surround an outer periphery of the heat sink 121 in the A view. Furthermore, the substrate 105 is also secured with four outer fasteners (i.e., screws) 133, which are disposed at vertices of a rectangular shape at locations positioned further outward of the four inner fasteners 131 in the A view.

Specifically in the present second embodiment, heights of four columns 135 to which the inner fasteners 131 are screwed is set to be slightly less than a distance from an upper surface of the substrate 105, on which the package component 107 is mounted, to a lower surface of the plate-shaped portion 137.

As a result, when the substrate 105 is secured to the columns 135 with the inner fasteners 131, a central portion of the substrate 105 (i.e., area where the package component 107 is disposed in the A view) deflects slightly downward. Therefore, the package component 107 is pressed upward by the substrate 105.

This second embodiment provides effects similar to those of the first embodiment.

### Third Embodiment

Since the basic configuration according to the third embodiment is the same as that of the first embodiment, the following description will mainly focus on the differences from the first embodiment. The members with the same names as those in the first embodiment have the same functions. The same reference numerals as those in the first embodiment indicate the same configuration, and reference is made to the preceding description.

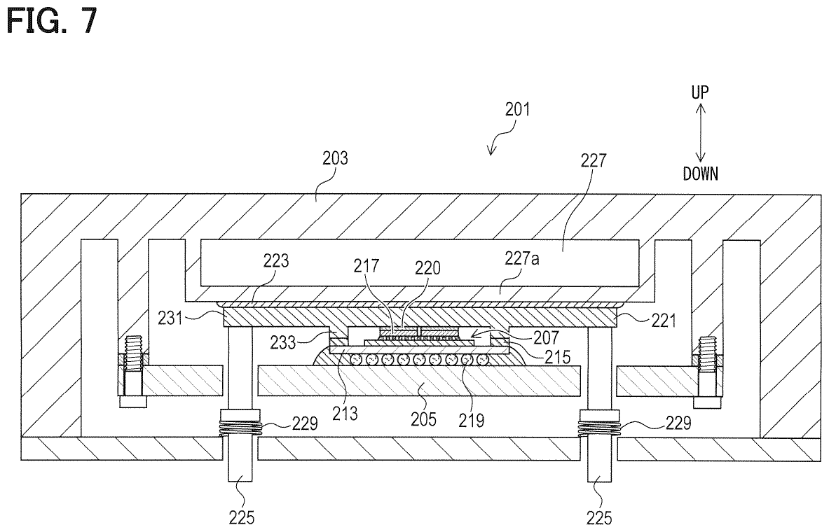

As shown in FIG. 7, an electronic device 201 according to the third embodiment is basically the same as that of the first embodiment except for a configuration of a heat sink 221. Specifically, the electronic device 201 includes components such as a housing 203, a substrate 205, and a package component 207, similar to those in the first embodiment. In detail, the package component 207 includes, for example, an interposer 213, a stiffener 215, and chips 217. The package component 207 is mounted on the substrate 205 via solder balls 219. The chips 217 is joined to the heat sink 221 via a solid first heat dissipating member 220. A gel-like second heat dissipating member 223 is disposed between the heat sink 221 and a lower portion 227a of a cooling section 227 of the housing 203. In addition, load-bearing components 225 are disposed and pressed upward by springs 229. The load-bearing components 225 press the heat sink 221 upward at positions located outward of the package component 207 in the A view.

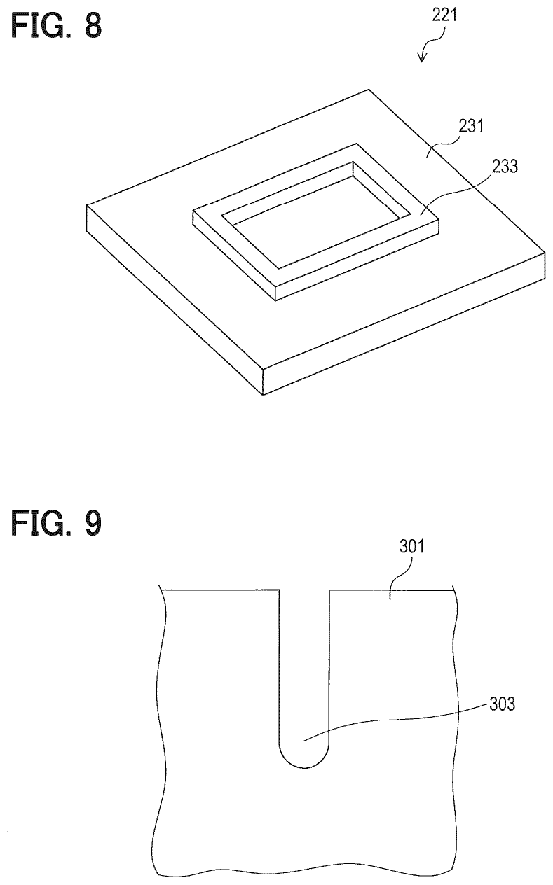

Specifically in the present second embodiment, as shown in FIG. 8, the heat sink 221 includes a flat portion 231 that is rectangular plate-shaped in the A view, and a frame portion 233 that is quadrilateral frame-shaped (i.e., rectangular-frame shaped) and provided at a center of the flat portion 231 in the A view. The flat portion 231 and the frame portion 233 are integrated, and centers of gravity of the flat portion 231 and the frame portion 233 coincide with each other in the A view.

The frame portion 233 protrudes from one surface of the flat portion 231 in its thickness direction (i.e., surface facing the package component 207: upper surface in FIG. 8). In addition, a shape of the frame portion 233 in the A view is made similar to that of the stiffener 215. In other words, the frame portion 233 is disposed along an outer periphery of the interposer 213 (i.e., along the stiffener 215) in the A view so as to surround components such as the chips 217, which are disposed in a central portion of the package component 207.

One surface of the frame portion 233 facing the package component 207 may be in contact with the stiffener 215, or may be spaced apart from the stiffener 215. The third embodiment has the same advantages as those of the first embodiment. It is preferable that the frame portion 233 is disposed so as to surround an entire periphery of the components such as the chips 217. However, the frame portion 233 may also be disposed so as to surround only a part of a periphery of these components.

### Other Embodiments

Although the embodiments of the present disclosure have been described above, the present disclosure is not limited to the embodiments described above, and various modifications can be made to implement the present disclosure.

In the embodiments of the present disclosure, the through-holes (i.e., load-bearing through-holes) through which the load-bearing components extend are provided in the substrate. However, instead of the through-holes, notches (e.g., notch 303 of substrate 301 in FIG. 9) may be provided in part or in whole. In other words, shaft portions of load-bearing components may be disposed in the notch.

In the present disclosure, the shapes of the substrate or the heat sink may be not only the rectangle but also other polygons. In other words, their planar shapes are not particularly limited.

In the present disclosure, the number of load-bearing components is not limited to four, and two or more of the components may be adopted.

In the present disclosure, the cooling section may be integrated with the housing or may be separate from the housing. If the cooling section is separated from the housing, for example, the housing and the cooling section may be joined so that an appropriate heat conduction is established between the housing and the cooling section.

Multiple functions of one element in the above embodiments may be implemented by multiple elements, or one function of one element may be implemented by multiple elements. In addition, multiple functions of multiple components may be realized by one component, or a single function realized by multiple components may be realized by one component. A part of the configuration of each of the embodiments described above may be omitted. At least the part of the configuration of each of the embodiments described above may be added to or substituted for a configuration of another embodiment.

What is claimed is:

1. An electronic device, comprising:
a housing;
a substrate disposed in the housing;
a package component including a chip and mounted on the substrate via solder;
a heat sink disposed between the housing and the chip and joined to the chip; and
load-bearing components disposed on an extended region of the heat sink where the heat sink extends outward of the package component when viewed in a thickness direction of the substrate, wherein
the load-bearing components press the heat sink in a direction from the substrate toward the heat sink.

2. The electronic device according to claim 1, wherein
the substrate includes a through-hole through which the load-bearing components extend to press the heat sink.

3. The electronic device according to claim 1, wherein
the substrate includes a notch through which the load-bearing components extend to press the heat sink.

4. The electronic device according to claim 1, wherein
each of the load-bearing components includes a holding portion located between the heat sink and a portion of the housing which are opposed to each other, and is pressed toward the heat sink by a spring disposed between the portion of the housing and the holding portion.

5. The electronic device according to claim 1, wherein
the substrate presses the package component toward the heat sink as a pressing structure.

6. The electronic device according to claim 1, wherein
the heat sink has a rectangular shape when viewed in the thickness direction of the substrate, and four corners of the heat sink are pressed by the load-bearing components, respectively, disposed at positions corresponding to the four corners of the heat sink.

7. The electronic device according to claim 1, further comprising
a solid first heat dissipating member that joins the chip and the heat sink together.

8. The electronic device according to claim 1, further comprising
a second heat dissipating member that is disposed between the heat sink and the housing and is in contact with both the heat sink and the housing.

9. The electronic device according to claim 8, wherein
the housing includes a cooling section facing the heat sink via the second heat dissipating member and configured to release a heat from the heat sink via the second heat dissipating member.

10. The electronic device according to claim 1, wherein
the heat sink includes a frame portion that protrudes toward the package component from a surface of the heat sink facing the package component, and the frame portion surrounds at least the chip.

11. The electronic device according to claim 1, further comprising
columns erected on an inner surface of the housing, wherein
the heat sink is mounted on the inner surface of the housing,
heights of the columns are less than a distance from the inner surface of the housing to a surface of the substrate on which the package component is mounted, and
the substrate is secured on surfaces of the columns facing away from the inner surface of the housing such that an area of the substrate where the package component is mounted is recessed in a direction away from the inner surface of the housing.
